(19) United States
(12) Patent Application Publication
(10) Pub. No.: US 2025/0393270 A1
(43) Pub. Date: Dec. 25, 2025

(54) SEMICONDUCTOR DEVICES WITH EPITAXIAL SOURCE/DRAIN REGION WITH A BOTTOM DIELECTRIC LAYER AND METHODS OF FABRICATION THEREOF

(71) Applicant: TAIWAN SEMICONDUCTOR MANUFACTURING COMPANY, LTD., Hsinchu (TW)

(72) Inventors: Cheng-Yu LIU, Hsinchu (TW); Sung-En LIN, Hsinchu (TW); Chung-Ting KO, Kaohsiung (TW); Shu Ling LIAO, Taichung (TW); Wen-Long LEE, Hsinchu (TW)

(21) Appl. No.: 18/749,746

(22) Filed: Jun. 21, 2024

(51) Int. Cl. H01L 29/08; H01L 21/762; H01L 21/764; H01L 29/06; H01L 29/423; H01L 29/66; H01L 29/775; H01L 29/786

(52) U.S. Cl. CPC H10D 62/151; H01L 21/76224; H01L 21/764; H10D 30/014; H10D 30/43; H10D 30/6735; H10D 30/6757; H10D 62/121; H10D 64/017; H10D 64/018

(57) ABSTRACT

Embodiments with present disclosure provides a gate-all-around FET device including a bottom isolation layer. The bottom isolation layer prevents leaks around the source/drain regions and improve device performance.

### BACKGROUND

The semiconductor industry has experienced continuous rapid growth due to constant improvements in the integration density of various electronic components. For the most part, this improvement in integration density has come from repeated reductions in minimum feature size, allowing more components to be integrated into a given chip area. As minimum feature size reduces, side effects, such as leakage, parasitic devices, resistance degradation, etc., may occur. Therefore, there is a need to solve the above problems.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart of a method for manufacturing of a semiconductor substrate according to embodiments of the present disclosure.

FIGS. 2A-2P schematically illustrate various stages of manufacturing a semiconductor device according to embodiments of the present disclosure.

FIGS. 3A-3C schematically illustrate a semiconductor device according to some embodiments of the present disclosure.

FIG. 4A-4B schematically illustrate a semiconductor device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The foregoing broadly outlines some aspects of embodiments described in this disclosure. While some embodiments described herein are described in the context of nanosheet channel FETs, implementations of some aspects of the present disclosure may be used in other processes and/or in other devices, such as planar FETs, Fin-FETs, Horizontal Gate All Around (HGAA) FETs, Vertical Gate All Around (VGAA) FETs, and other suitable devices. A person having ordinary skill in the art will readily understand other modifications that may be made are contemplated within the scope of this disclosure. In addition, although method embodiments may be described in a particular order, various other method embodiments may be performed in any logical order and may include fewer or more steps than what is described herein. In the present disclosure, a source/drain region refers to a source and/or a drain. A source and a drain are interchangeably used.

The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process.

Embodiments of the present disclosure relate to a semiconductor device including high quality bottom isolation layers at bottom surfaces of the source/drain regions. The bottom isolation layer prevents leak between the source/drain regions across a gate structure via semiconductor regions below the gate structure, sometimes referred to as mesa regions. Traditionally, the bottom isolation layer is formed using several lithographic masks and may exhibit poor quality. Embodiments of the present disclosure provide a selective gap fill process to form the bottom isolation layer. In some embodiments, a first material layer is deposited over tops, sidewalls and bottoms of high aspect ratio trenches between neighboring gate structures. A trim process is performed to remove a portion of the first material from the top and sidewalls. Then a treatment process is performed to convert the first material layer into a dielectric-containing material layer. For example, the treatment process may convert at least a portion of the first material layer into a dielectric material. The deposition, trim and treatment processes may be performed once or multiple times until the dielectric material layer at the bottom of the trench reaches a desired thickness. An etch process may be performed to remove the dielectric materials from tops and sidewalls of the trenches, resulting in a high-quality bottom isolation layer. Epitaxial process is then performed for form the source/drain region over the bottom isolation layer.

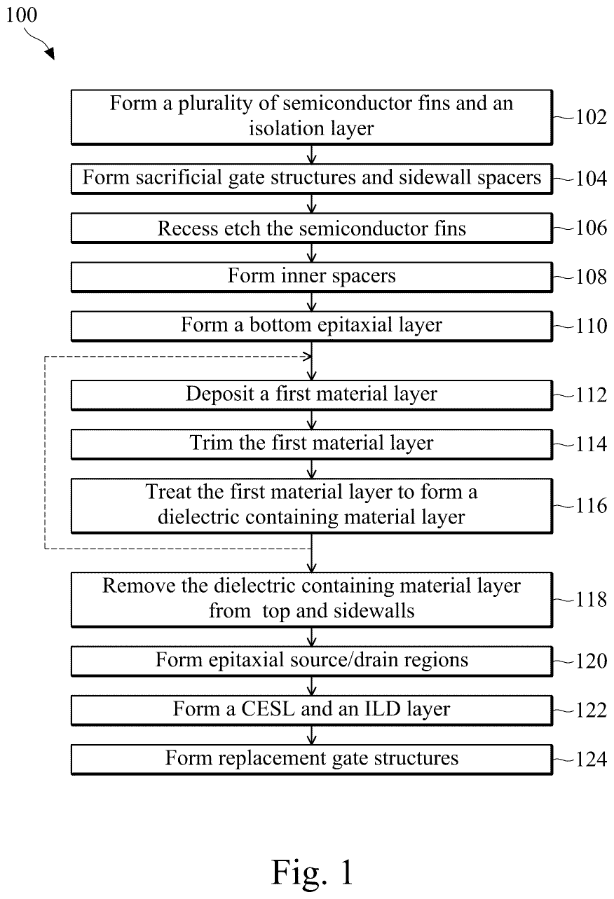

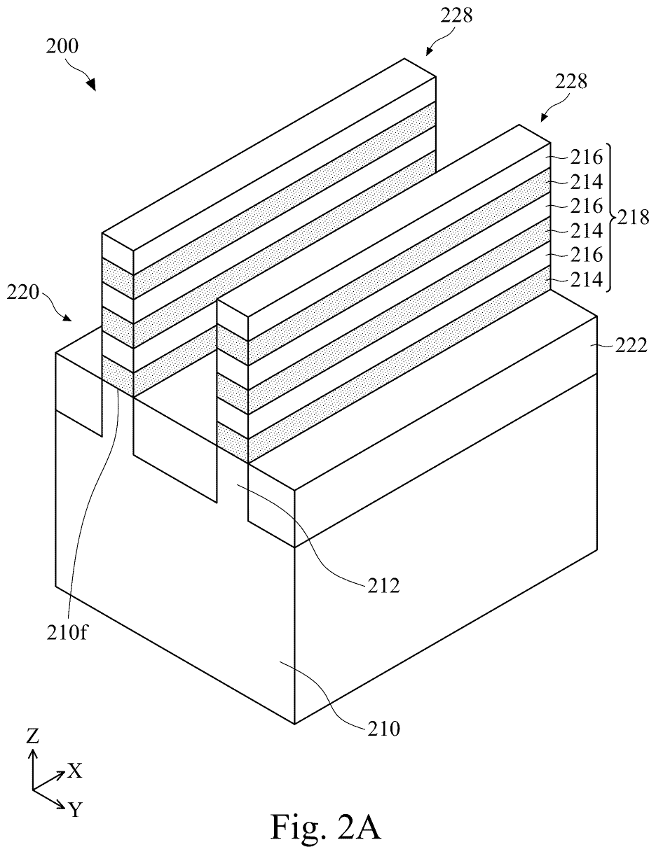

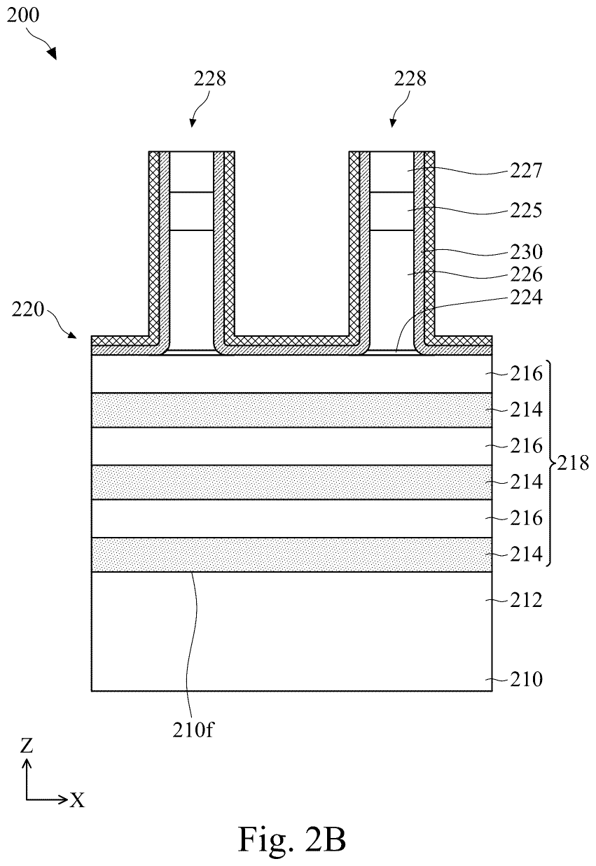

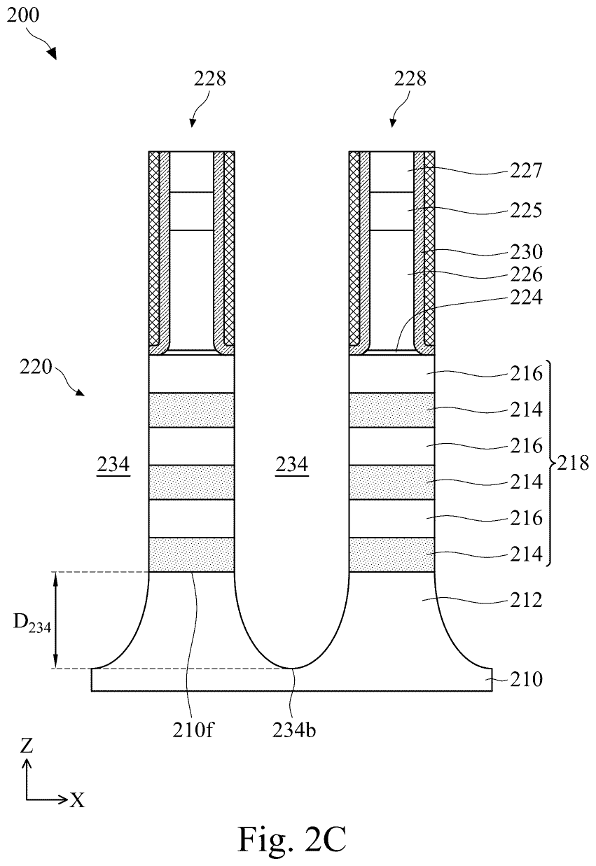

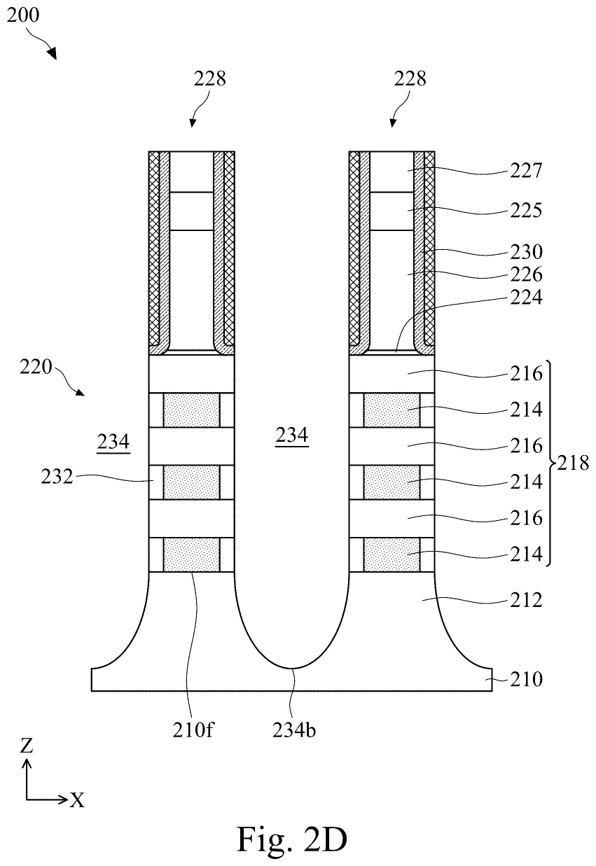

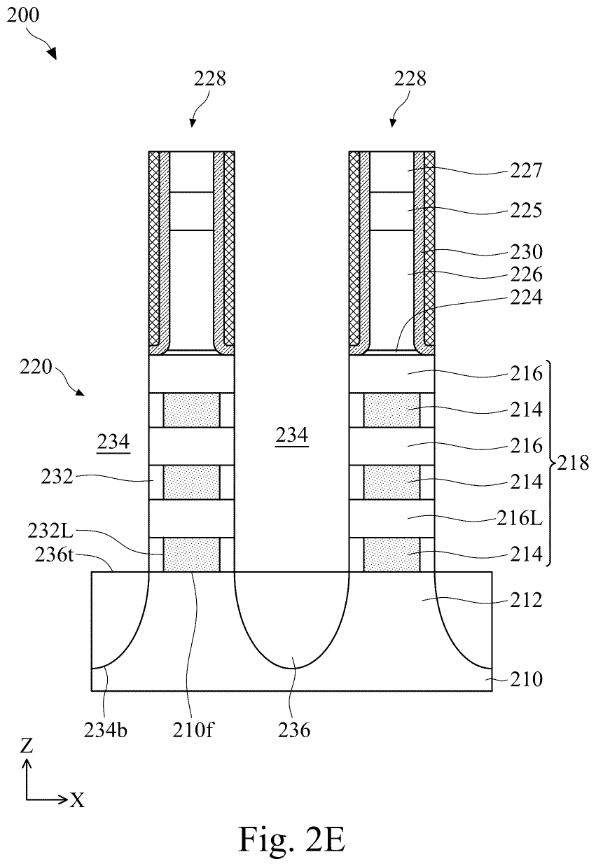

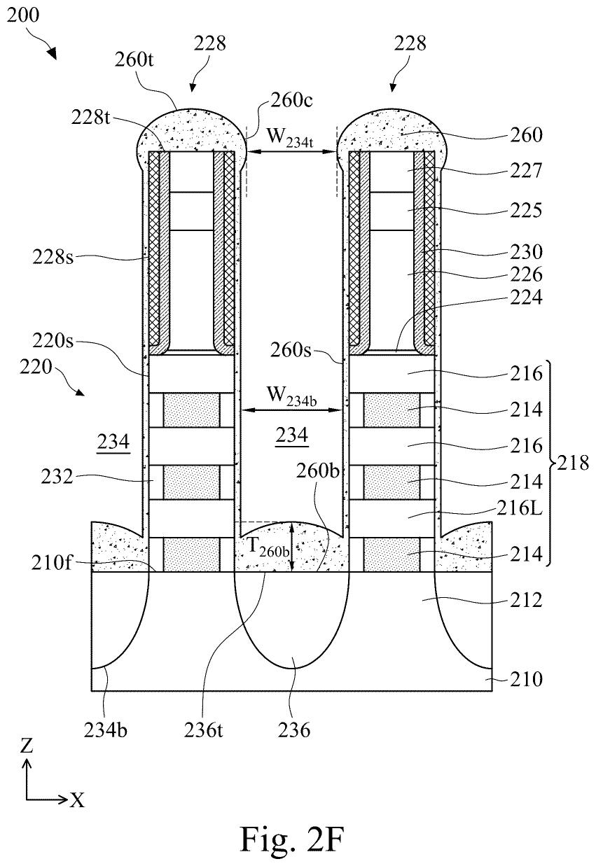

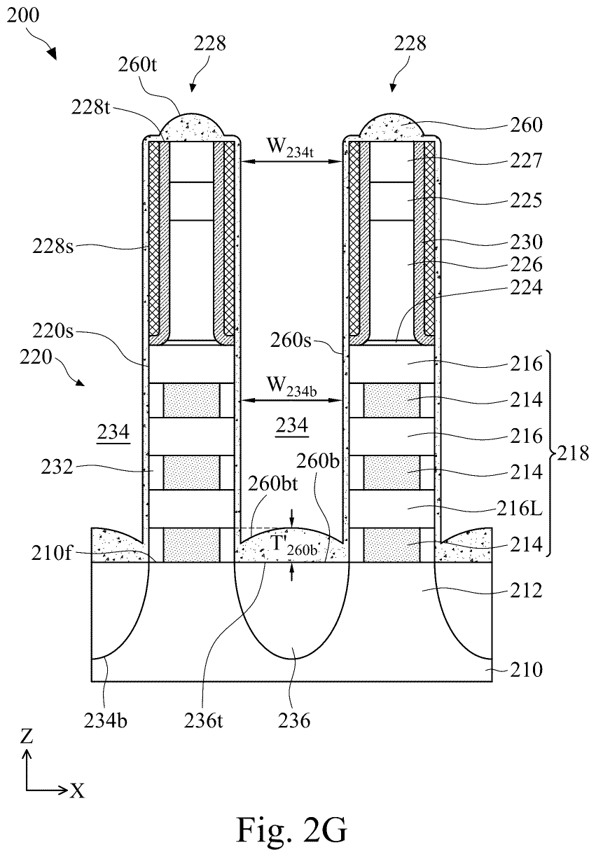

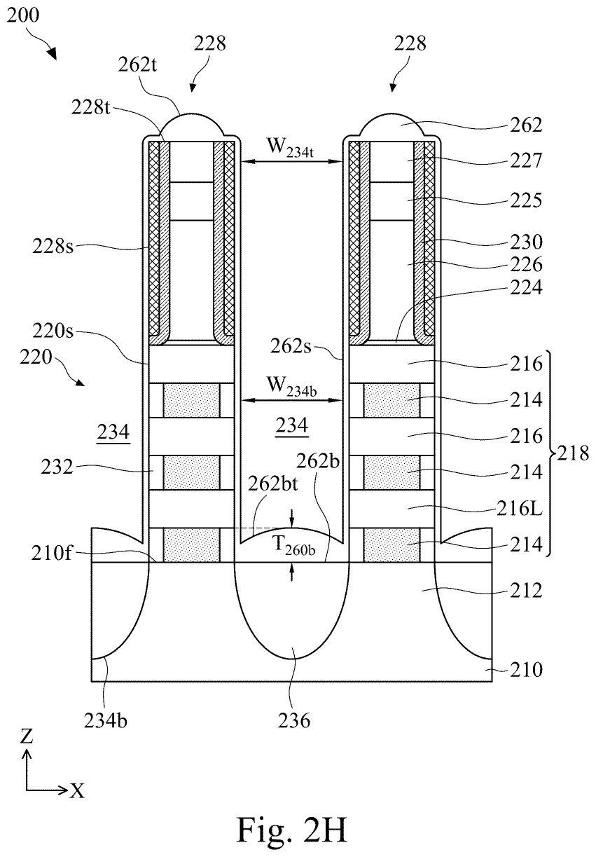

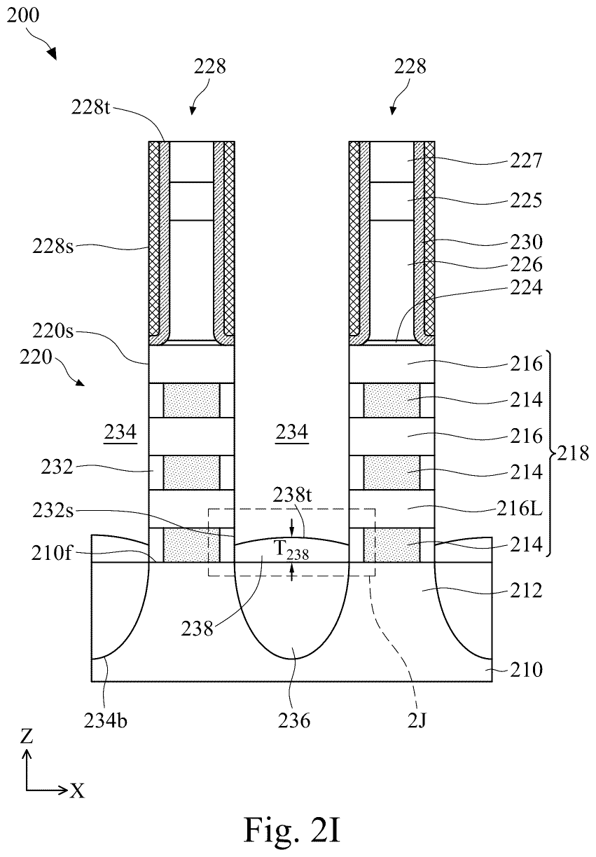

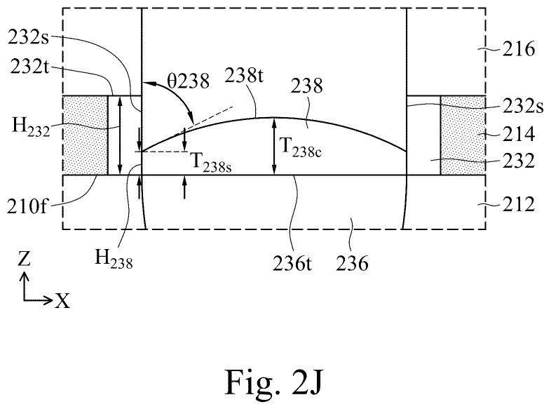

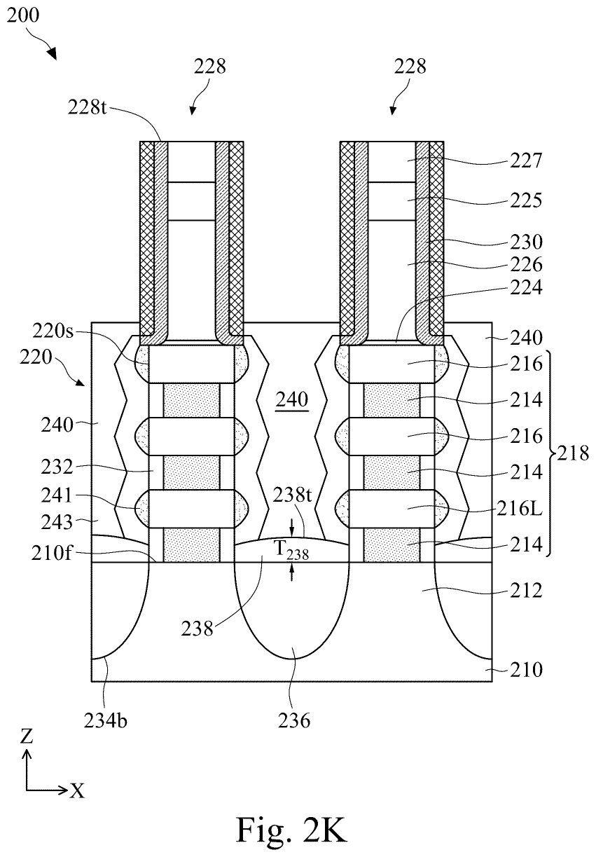

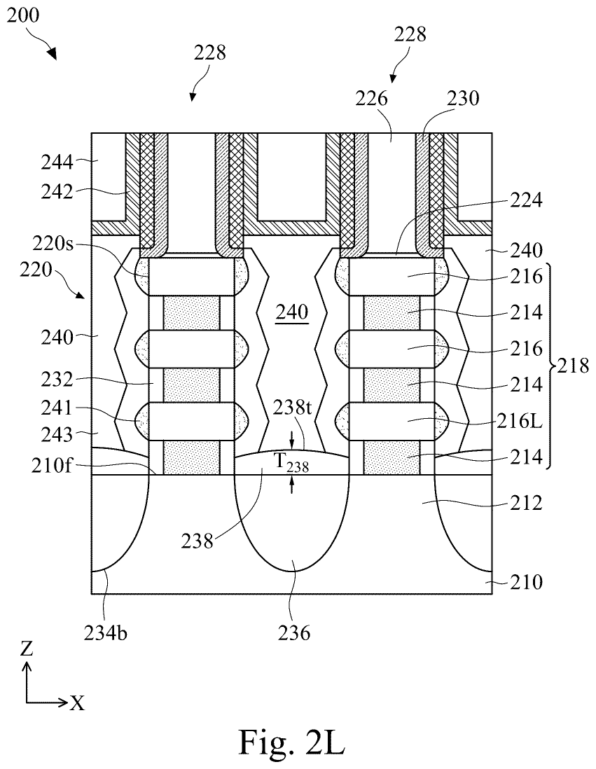

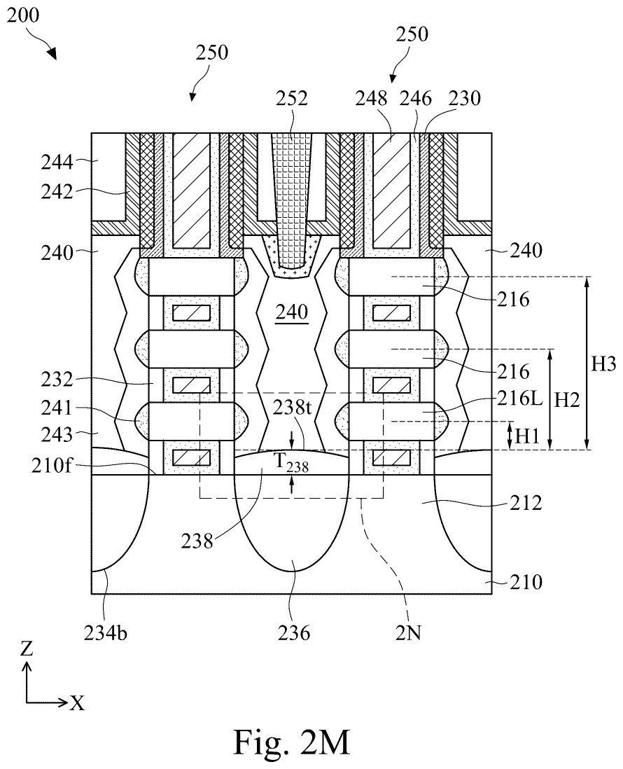

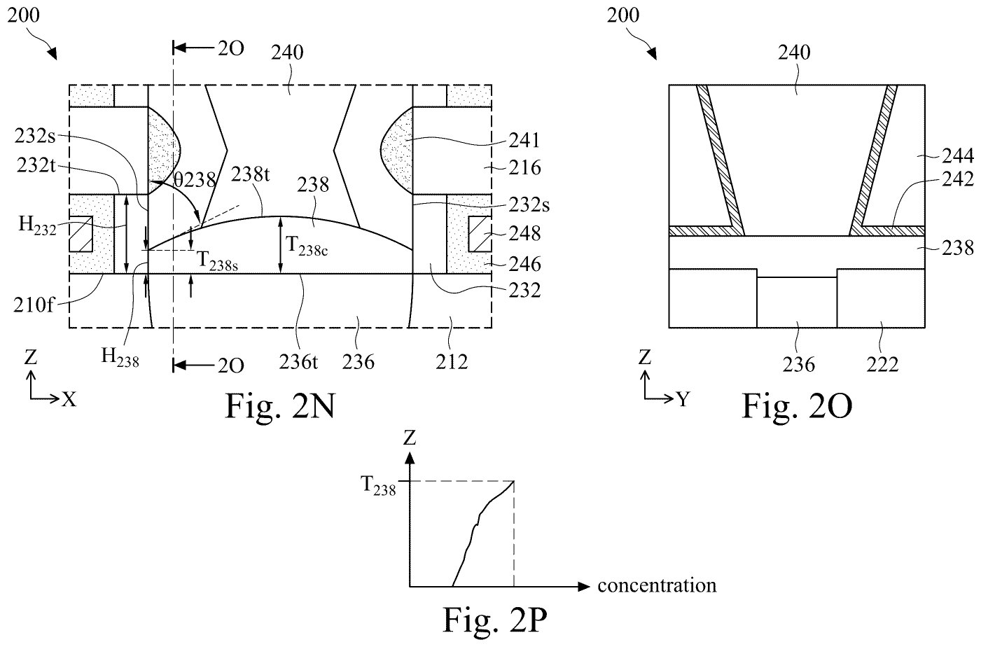

FIG. 1 is a flow chart of a method 100 for manufacturing of a semiconductor device according to embodiments of the present disclosure. FIGS. 2A-2P schematically illustrate various stages of manufacturing a semiconductor device 200 according to embodiments of the present disclosure.

The method 100 begins at operation 102 where a plurality of semiconductor fins 220 are formed over a substrate 210, as shown in FIG. 2A. FIG. 2A is a schematic perspective view of the semiconductor device 200 after operation 102. The substrate 210 is provided to form the semiconductor device 200 thereon. The substrate 210 may include a single crystalline semiconductor material such as, but not limited to Si, Ge, SiGe, GaAs, InSb, GaP, GaSb, InAIAs, InGaAs, GaSbP, GaAsSb, and InP. The substrate 210 may include various doping configurations depending on circuit design. For example, different doping profiles, e.g., n-wells, p-wells, may be formed in the substrate 210 in regions designed for different device types, such as n-type field effect transistors (NFET), and p-type field effect transistors (PFET). In some embodiments, the substrate 210 may be a silicon-on-insulator (SOI) substrate including an insulator structure (not shown) for enhancement.

The substrate 210 has a front surface 210f. A semiconductor stack 218 is then formed over the front surface 210f of the substrate 210. The semiconductor stack includes alternating semiconductor layers made of different materials to facilitate formation of nanosheet channels in a multi-gate device, such as nanosheet channel FETs. In some embodiments, the semiconductor stack includes first semiconductor layers 214 interposed by second semiconductor layers 216. The first semiconductor layers 214 and second semiconductor layers 216 have different oxidation rates and/or etch selectivity. In some embodiments, the front surface 210f of the substrate 210 may have (100) orientation or (110) orientation. The orientation of the front surface 210f determines the orientation of the layers in the semiconductor stack 218, and epitaxial features, such as epitaxial source/drain regions formed from the semiconductor channel layers in the semiconductor stack 218.

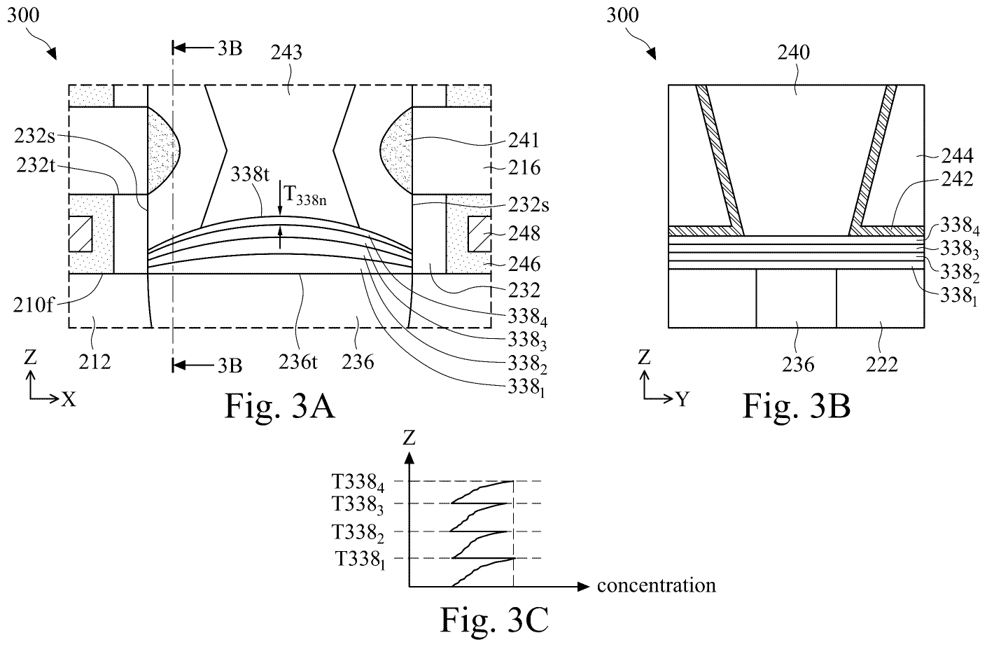

In later fabrication stages, portions of the second semiconductor layers 216 form nanosheet channels in a multi-gate device. Three first semiconductor layers 214 and three second semiconductor layers 216 are alternately arranged as illustrated in FIG. 3A as an example. More or less semiconductor layers 214 and 216 may be included in the semiconductor stack depending on the desired number of channels in the semiconductor device to be formed. In some embodiments, the number of semiconductor layers 216 is between 1 and 6.

The semiconductor layers 214, 216 may be formed by a molecular beam epitaxy (MBE) process, a metalorganic chemical vapor deposition (MOCVD) process, and/or other suitable epitaxial growth processes. In some embodiments, the semiconductor layers 216 include the same material as the substrate 210. In some embodiments, the semiconductor layers 214 and 216 include different materials than the substrate 210. In some embodiments, the semiconductor layers 214 and 216 are made of materials having different lattice constants. In some embodiments, the first semiconductor layers 214 include an epitaxially grown silicon germanium (SiGe) layer and the second semiconductor layers 216 include an epitaxially grown silicon (Si) layer. Alternatively, in some embodiments, either of the semiconductor layers 214 and 216 may include other materials such as Ge, a compound semiconductor such as SiC, GeAs, GaP, InP, InAs, and/or InSb, an alloy semiconductor such as SiGe, GaAsP, AllnAs, AlGaAs, InGaAs, GalnP, and/or GalnAsP, or combinations thereof.

The first semiconductor layers 214 in channel regions may eventually be removed and serve to define a vertical distance between adjacent channels for a subsequently formed multi-gate device. In some embodiments, the thickness of the first semiconductor layer 214 is equal to or greater than the thickness of the second semiconductor layer 216. In some embodiments, each semiconductor layer 214 has a thickness in a range between about 3 nm and about 15 nm. In some embodiments, each second semiconductor layer 216 has a thickness in a range between about 3 nm and about 15 nm. In some embodiments, the second semiconductor layers 216 in the semiconductor stack are uniform in thickness.

The semiconductor fins 220 are formed from the semiconductor stack and a portion of the substrate 210. The semiconductor fins 220 may be formed by patterning a hard mask (not shown) formed on the semiconductor stack and one or more etching processes. Each semiconductor fin 220 has a channel portion 218 formed from the semiconductor layers 214, 216 and a well portion 212 formed from the substrate 210. The semiconductor fins 220 are formed along the X direction.

An isolation layer 222 is formed in the trenches between the semiconductor fins 220. The isolation layer is formed over the substrate 210 to cover the well portion 212 of the semiconductor fins 220. The isolation layer may be formed by a high-density plasma chemical vapor deposition (HDP-CVD), a flowable CVD (FCVD), or other suitable deposition process. In some embodiments, the isolation layer 222 may include silicon oxide, silicon nitride, silicon oxynitride, fluorine-doped silicate glass (FSG), a low-k dielectric, combinations thereof. In some embodiments, the isolation layer is formed to cover the semiconductor fins 220 by a suitable deposition process, such as atomic layer deposition (ALD), and then recess etched using a suitable anisotropic etching process to expose the channel portions 218 of the semiconductor fins 220.

In operation 104, sacrificial gate structures 228 and spacer layers 230 are then formed over the semiconductor fins 220, as shown in FIG. 2B. FIG. 2B is schematic cross-sectional view of the semiconductor device 200. A sacrificial gate dielectric layer 224 is deposited over the exposed surfaces of the semiconductor device 200. The sacrificial gate dielectric layer 224 may be formed conformally over the semiconductor fins 220, and the isolation layer 222. In some embodiments, the sacrificial gate dielectric layer 224 may be deposited by a CVD process, a sub-atmospheric CVD (SACVD) process, a FCVD process, an ALD process, a PVD process, or other suitable process. The sacrificial gate dielectric layer 224 may include one or more layers of dielectric material, such as SiO₂, SiN, a high-K dielectric material, and/or other suitable dielectric material.

A sacrificial gate electrode layer 226 is deposited over the sacrificial gate dielectric layer 224. The sacrificial gate electrode layer 226 may be blanket deposited on the over the sacrificial gate dielectric layer 224. The sacrificial gate electrode layer 226 includes silicon such as polycrystalline silicon or amorphous silicon. In some embodiments, the sacrificial gate electrode layer 226 is subjected to a planarization operation. The sacrificial gate electrode layer 226 may be deposited using CVD, including LPCVD and PECVD, PVD, ALD, or other suitable process. Subsequently, a pad layer 225 and a mask layer 227 are formed over the sacrificial gate electrode layer 226. The pad layer 225 may include silicon nitride. The mask layer 227 may include silicon oxide. Next, a patterning operation is performed on the mask layer 227, the pad layer 225, the sacrificial gate electrode layer 226, and the sacrificial gate dielectric layer 224 to form the sacrificial gate structures 228, which cover formed over portions of the semiconductor fins 220 designed to be channel regions.

Gate sidewall spacers 230 are then formed on sidewalls of each sacrificial gate structures 228. After the sacrificial gate structures 228 are formed, the gate sidewall spacers 230 may be formed by a blanket deposition of an insulating material followed by anisotropic etch to remove insulating material from horizontal surfaces. The gate sidewall spacers 230 may have a thickness in a range between about 3 nm and about 8 nm. In some embodiments, the insulating material of the gate sidewall spacers 230 is a silicon nitride-based material, such as SIN, SiON, SiOCN or SiCN and combinations thereof. In FIG. 2B, the gate sidewall spacers 230 include two layers. In other embodiments, the gate sidewall spacers 230 may be formed from less or more layers of dielectric materials.

In operation 106, the semiconductor fins 220 on opposite sides of the sacrificial gate structure 228 are recess etched, forming source/drain recesses 234 between the neighboring sacrificial gate structures 228, as shown in FIG. 2C. FIG. 2C is schematic cross-sectional view of the semiconductor device 200. The first semiconductor layers 214 and the second semiconductor layers 216 in the semiconductor fins 220 are etched down on both sides of the sacrificial gate structures 228 using etching operations. In some embodiments, all layers in the semiconductor stack 218 of the semiconductor fins 220 and a portion of the well portions 212 of the semiconductor fins 220 are etched. In some embodiments, suitable dry etching and/or wet etching may be used to remove the first semiconductor layers 214, the second semiconductor layers 216, and the substrate 210.

In some embodiments, the source/drain recesses 234 are deep trenches formed below the top surface 210f of the substrate 210. In some embodiments, the source/drain recess 234 has a drop distance D₂₃₄, which is defined by the distance between the top surface 210f of the substrate 210 or a sheet bottom to a bottom 234b of the source/drain recesses 234. In some embodiments, the drop distance D₂₃₄ is in a range between about 3 nm and about 50 nm.

In operation 108, inner spacers 232 are formed on exposed ends of the first semiconductor layers 214 under the sacrificial gate structures 228, as shown in FIG. 2D. The first semiconductor layers 214 exposed to the source/drain recesses 234 are first etched horizontally along the X direction to form spacer cavities. In some embodiments, the first semiconductor layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. In some embodiments, the amount of etching of the first semiconductor layer 214 is in a range between about 5 nm and about 10 nm along the X direction.

After forming the spacer cavities at opposite ends of the first semiconductor layers 214, the inner spacers 232 can be formed in the spacer cavities by conformally depositing an insulating layer and then partially removed to form the inner spacer 232 as shown in FIG. 2D. The insulating layer can be formed by ALD or any other suitable method. The subsequent etch process removes most of the insulating layer except inside the cavities, resulting in the inner spacers 232. The inner spacers 232 includes two or more segments, alternately stacked with the second semiconductor layers 216.

The inner spacers 232 may be formed from a single layer or multiple layers of dielectric material. In some embodiments, the inner spacers 232 may include one of silicon nitride (SiN) and silicon oxide (SiO₂), SiONC, or a combination thereof. The inner spacer 232 may have a thickness in a range from about 5 nm to about 10 nm along the X direction.

In operation 110, a bottom epitaxial layer 236 is formed in lower portions of the source/drain recesses 234, as shown in FIG. 2D. In some embodiments, the bottom epitaxial layer 236 fills the lower portions of the source/drain recesses 234 to a level below the bottom most semiconductor layer 216L, or the bottom most channel region. In some embodiments, the bottom epitaxial layer 236 fill the source/drain recesses 234 to a level below the bottom most inner spacers 232L. In some embodiment, a front surface 236f may be at a level below the bottom most inner spacers 232L. In some embodiments, the front surface 236f is below the top surface 210f of the substrate 210 and a portion of mesa sidewall 212s is exposed to the source/drain recess 234 after formation of the bottom epitaxial layer 236.

The material and shape of the bottom epitaxial layer 236 may be selected according to achieve one or more purposes. For example, the bottom epitaxial layer 236 may provide crystalline transition from the substrate 210 to the subsequently formed source/drain region with improved adhesion. The bottom epitaxial layer 236 may define a bottom profile and crystalline direction of the subsequently formed source/drain region. In some embodiments, the bottom epitaxial layer 236 may also function as an alignment feature for back side source/drain contacts.

In some embodiments, the bottom epitaxial layer 236 may be formed from a material to have etch selectivity relative to the material of the substrate 210, such as material in the well portion 212 of the semiconductor fin 220. In some embodiments, the bottom epitaxial layer 236 may also have etch selectivity relative to the insulating material in the isolation layer. In some embodiments, the bottom epitaxial layer 236 are formed from a semiconductor material with a high etch selectivity relative to Si. For example, the bottom epitaxial layer 236 are formed are formed from SiGe.

The bottom epitaxial layer 236 may be formed by any suitable method, such as by CVD, CVD epitaxy, molecular beam epitaxy (MBE), or any suitable deposition technique. In some embodiments, the bottom epitaxial layer 236 are formed from undoped SiGe. In some embodiments, the bottom epitaxial layer 236 are formed from undoped SiGe including an atomic concentration of Ge in a range between about 10% and about 100%. Alternatively, the bottom epitaxial layer 236 may include other materials, such as Ge, a compound semiconductor such as SiC, GeAs, GaP, InP, InAs, and/or InSb, an alloy semiconductor such as GaAsP, AllnAs, AlGaAs, InGaAs, GalnP, and/or GalnAsP, or combinations thereof.

In operations 112, 114, 116 and 118, a bottom isolation layer is formed over the bottom epitaxial layer 236. Particularly, the operations 112, 114, 116, and 118 provide a method for forming a dielectric layer at a bottom surface of the source/drain recesses 234. In operation 112, a first material is deposited over all surfaces. In operation 114, a trimming process is performed to remove portions of the first material, such as overhang portions at trench openings and vertical sidewall portions. In operation 116, a treatment process is performed to convert the trimmed first material to a dielectric material. In operation 118, an etch process is performed to remove sidewall portion of the dielectric material, while the bottom portion of the dielectric layer remains to form a bottom isolation layer over the bottom epitaxial layer 236. The operations 112, 114, 116, 118 are described in detail with FIGS. 2F-21.

In operation 112, a first material layer 260 is deposited over the semiconductor device 200, as shown in FIG. 2F. FIG. 2F is a schematic cross-sectional view of the semiconductor device 200. The first material layer 260 may cover all exposed surfaces on the semiconductor device 200. In some embodiments, the first material layer 260 is an intermediate material layer of the bottom isolation layer. In some embodiments, the first material layer 260 may be a silicon layer or a metal layer. The first material layer 260 may be formed by a suitable deposition process, such as chemical vapor deposition, physical vapor deposition, plasma enhanced vapor deposition, or any suitable process.

In some embodiments, the first material layer 260 is a silicon layer. In some embodiments, the first material layer 260 is a metal layer, such as aluminum, hafnium, zirconium, or a combination. In another embodiments, the first material layer 260 may include a combination of silicon and metal, such as a combination of silicon and hafnium.

In some embodiments, the first material layer 260 is a silicon layer formed using a silicon containing precursor, such as SiₓH₂ₓ₊₂, wherein x=1˜4, or any suitable silicon containing percussor. For example, the first material layer 260 may be deposited using a precursor comprising SiH₄ (silane), Si₂H₆ (disiliane), Si₃H₈ (trisiliane), Si₄H₁₀ (tetrasiliane), or a combination thereof. The silicon layer may be formed in a temperature range between about 150° C. and about 550° C. The process pressure may be in a range between about 10 mtorr and 1 torr.

In some embodiments, the first material layer 260 may be deposited in an anisotropic process. As shown in FIG. 2F, the first material layer 260 is deposited thicker on horizontal surfaces and thinner on vertical surfaces. The anisotropic deposition may be achieved by applying a vertical bias to the reactant gas during deposition. In FIG. 2F, the first material layer 260 has a top portion 260t deposited on top surfaces 228t of the sacrificial gate structures 228, a bottom portion 260b deposited on top surfaces 236t of the bottom epitaxial layer 236 or bottoms of the source/drain recesses 234, sidewall portions 260s on sidewalls 228s of the sacrificial gate structures 228 and exposed sidewalls 220s of recessed fin structures 220. The top portion 260t and the bottom portion 260b are thicker while the sidewall portions 260s are thinner. The bottom portion 260b has a thickness T_{260b}. In some embodiments, the thickness T_{260b} is in a range between about 0.8 nm and about 5.0 nm.

As the critical dimension of the semiconductor device 200 shrinks, the source/drain recesses 234 between the sacrificial gate structures 228 are high aspect ratio trenches. Film deposition over high aspect ratio trenches typically result in overhang near entrances of the trenches. As shown in FIG. 2F, the first material layer 260 may include hangover portions 260c at entrance of the source/drain recesses 234. The hangover portions 260c may pinch off the entrance of the source/drain recesses 234. As shown in FIG. 2F, the source/drain recesses 234 have a top width W₂₃₄ₜ between the hangover portions 260c and a bottom width W_{234b} below the entrance. After deposition of the first material layer 260, the top width W₂₃₄ₜ is narrower than the bottom width W_{234b}. The narrower top width W₂₃₄ₜ may limit access of processing gases to within the source/drain recesses 234.

In operation 114, a trimming process is performed to remove portions of the first material layer 260, as shown in FIG. 2G. FIG. 2G is a schematic cross-sectional view of the semiconductor device 200. The trimming process may be performed by supplying etching reactant to remove a portion of the first material layer 260, particularly, to substantially remove overhang portions 260c and part of the sidewall portions 260s. The trimming process may also remove a portion of the bottom portion 260b of the first material layer 260. After the trimming process, the bottom portion 260b has a reduced thickness T′_{260b}. In some embodiments, the thickness T′_{260b} is in a range between about 0.5 nm and about 4.5 nm. In some embodiments, as shown in FIG. 2G, a top surface 260bt of the bottom portion 260b may have a convex profile which is higher near the center and lower near the inner spacers 232.

After the trimming process, the top width W₂₃₄ₜ at of the source/drain recesses 234 widens, allowing the source/drain recesses 234 to have adequate accesses of processing chemistry in the subsequent process.

In some embodiments, the trimming process may be performed by supplying trimming chemicals to the surfaces of the first material layer 260. The trimming chemicals may gas comprising hydrogen (H₂), chlorine (Cl₂), nitrogen trifluoride (NF₃), or a combination thereof. The trimming chemicals react and remove the sidewall portions 260s of the first material layer 260, therefore, act as an inhibitor to formation of the first material layer 260 on the sidewalls 220s, 228s. Alternatively, the processing gas may be any reactant suitable to etch the first material layer. In some embodiments, the trimming process may be performed in a temperature range between about 150° C. and about 550° C. The process pressure may be in a range between about 10 mtorr and 50 torr.

In some embodiments, the deposition process in operation 112 and the trimming process in operation 114 may be processed in the same chamber. Alternatively, the deposition process in operation 112 and the trimming process in operation 114 may be performed in two separate chambers.

In operation 116, a treatment process is performed to convert the trimmed first material layer 260 to a dielectric-containing material layer, for example a dielectric material layer 262, as shown in FIG. 2H. FIG. 2H is a cross-sectional view of the semiconductor device 200. The dielectric material layer 262 may be a silicon containing compound, a metal oxide, or other suitable dielectric material. In some embodiments, the dielectric material layer 262 may comprise one or more silicon containing dielectric material, such as silicon oxide (SiO), silicon nitride (SiN), silicon carbide (SiC), silicon-oxy-carbide (SiOC), silicon nitride carbide (SiCN), silicon oxy nitride carbide (SiONC), or a combination. In some embodiment, the dielectric layer 262 may comprises one or more metal oxides, such as Al₂O₃, HfO₂, ZrO₂, HfAlOₓ, HfSiOₓ, or other suitable dielectric material.

In some embodiments, the treatment process may include exposing the trimmed first material layer 260 in a treatment gas to facilitate a chemical reaction between the treatment gas and the first material layer 260, thereby, converting the first material layer 260 into the dielectric material layer 262. In some embodiments, the dielectric material layer 262 has substantially the same dimension as the trimmed first material layer 260. In FIG. 2H, the dielectric material layer 262has a top portion 262t formed on the top surfaces 228t of the sacrificial gate structures 228, a bottom portion 262b formed on the top surfaces 236t of the bottom epitaxial layer 236 or the bottoms of the source/drain recesses 234, sidewall portions 262s on the sidewalls 228s of the sacrificial gate structures 228 and the exposed sidewalls 220s of recessed fin structures 220. The bottom portion 262b is thicker while the sidewall portions 262s are thinner. The bottom portion 262b has a thickness T_{262b}. In some embodiments, the thickness T_{262b} is in a range between about 0.5 nm and about 4.5 nm. In some embodiments, as shown in FIG. 2F, a top surface 262bt of the bottom portion 262b may have a convex profile which is higher near the center and lower near the inner spacers 232.

In some embodiments, the treatment gas may be an oxygen containing gas, a nitrogen containing gas, a carbon containing gas, or a combination thereof. In some embodiments, the treatment gas may include an oxygen source, such as oxygen (O₂), ozone (O₃), a combination, or the likes, to convert the first material layer 260 into a silicon oxide, a metal oxide, or a combination. In some embodiments, the treatment gas may include a nitrogen source, such as nitrogen (N₂), a mixture of nitrogen and hydrogen (N₂/H₂), nitrogen oxide (N₂O), ammonia (NH₃), a combination, or the likes, to convert the first material layer 260 into a silicon nitride. In some embodiments, the treatment gas may include a carbon source, such as methane (CH₄), or the likes, to convert the first material layer 260 into a silicon carbide. In some embodiments, the treatment process may be performed in a temperature range between about 150° C. and about 550° C. The process pressure may be in a range between about 10 mtorr and 50 torr.

In some embodiments, after the treatment process, in the bottom portion 262b, the added element, such as oxygen, nitrogen, and carbon, may have a concentration gradient decreasing from the top surface 262bt to the top surface 236t of the bottom epitaxial layer 236.

In some embodiments, the treatment process in operation 116 may be performed in the same chamber as the deposition process in operation 112 and the trimming process in operation 114. In some embodiments, the treatment process in operation 115 and the trimming process in operation 114 are performed in the same process chamber while the deposition process in operation 112 is performed in a separate chamber.

Depending on the design of the semiconductor device 200 and the thickness T₂₆₂ b of the bottom portion 262b after the treatment process in operation 116, operations 112, 114, and 116 may be repeated one or more times so that the bottom portion 262b reach a target thickness to provide isolation between the subsequently formed source/drain feature and the well portion 212. After the bottom portion 262b reaches a target thickness, the operation 118 is performed to remove the dielectric material layer 262 from the sidewalls.

In operation 118, an etch process is performed to completely remove sidewall portion 262s of the dielectric material layer 262, while the bottom portion 262b of the dielectric material layer 262 remains to form a bottom isolation layer 238 to cover the bottom epitaxial layer 236, as shown in FIG. 21. FIG. 21 is a schematic cross- sectional view of the semiconductor device 200.

In some embodiments, the etch process may be any suitable etch process, such as a dry etch process, a wet etch process, or a combination thereof. The etch process is performed to remove the sidewall portion 262s of the dielectric material layer 262, while substantially portion of the bottom portion 262b of the dielectric material layer 262 remains. As described above, the sidewall portion 262s of the dielectric material layer 262 is substantially thinner than the bottom portion 262b of the dielectric material layer 262 because of the trimming process in operation 114. As a result, the etch process completely removes the sidewall portion 262s of the dielectric material layer 262 while the bottom portion 262b of the dielectric material layer 262 is reduced in thickness.

After operation 118, the bottom isolation layer 238 has a thickness T₂₃₈. In some embodiments, the thickness T₂₃₈ of the bottom isolation layer 238 is in a range between from about 3.5 nm and about 5.0 nm, for example, in a range between about 3.7 nm and 4.3 nm. A thickness T₂₃₈ less than 3.5 nm may not provide sufficient electrical isolation around the subsequently formed source/drain regions, while a thickness T₂₃₈ greater than 5.0 nm may cause unnecessary loss of source/drain volume without additional benefit in isolation.

FIG. 2J is a partially enlarged view of the semiconductor device 200 in a rectangular area 2J marked in FIG. 21. As shown in FIG. 2J, the bottom isolation layer 238 extends between two inner spacers 232 on opposite sides of the source/drain recess 234. A top surface 238t of the bottom isolation layer 238 ends at side surfaces 232s of the bottom most inner spacers 232. The bottom isolation layer 238 is in contact with the inner spacers 232, therefore, preventing the subsequently formed source/drain region to be in contact with the well portion 212 under the gate structures.

After operation 118, the top surface 238t of the bottom isolation layer 238 may remain convex which is higher near the center region and lower near the inner spacers 232. The top surface 238t of the bottom isolation layer 238 and the side surface 232s of the bottom most inner spacer 232 form an angle θ₂₃₈. In some embodiments, the angle θ₂₃₈ is in a range between about 55° and about 90°.

In some embodiments, the bottom isolation layer 238 may have a center thickness T_{238c} greater than a side thickness T₂₃₈ₛ. In some embodiments, the difference between the center thickness T_{238c} greater and the side thickness T₂₃₈ₛ may be less than about 0.6 nm. Compared to the bottom isolation layers formed using lithographic patterning process, the bottom isolation layer 238 according to the present disclosure has a reduced thickness difference across the length along the x-direction, or between the inner spacers 232 on opposite sides of the source/drain recess 234. A rate of thickness variation r1 is defined by a ratio of thickness difference over the largest thickness. In the embodiment of FIG. 1J, the rate thickness variation may be defined by

$$r 1 = \frac{{T}_{238 c} - {T}_{238 s}}{{T}_{238 c}}$$

In some embodiment, r1 is less than 15%.

In some embodiments, the top surface 238t of the bottom isolation layer 238 may be in a level within the bottom most inner spacers 232. As shown in FIG. 1J, a top surface 232t of the bottom most inner spacers 232 is located at a height H₂₃₂ from the mesa surface 210f along the z-direction. The top surface 238t of the bottom isolation layer 238 intersects with the sidewall 232s of the bottom most inner spacers 232 at a height H₂₃₈ from the mesa surface 210f along the z-direction. In some embodiments, a ratio of the height H₂₃₂ over the height H₂₃₈ is in a range between about 0.5 and about 0.9.

In operation 120, epitaxial source/drain regions 240 are formed in the source/drain recesses 234, as shown in FIG. 2K. FIG. 2K is a schematic cross-sectional view of the semiconductor device 200. In some embodiments, the epitaxial source/drain regions 240 may include one or more layers of epitaxially formed semiconductor layers. In some embodiments, the epitaxial source/drain regions 240 may include a first epitaxial source/drain layer 241 and a bulk epitaxial source/drain layer 243.

In some embodiments, a preclean process may be performed prior to epitaxial growth of the first epitaxial source/drain layer 241. The first epitaxial source/drain layer 241 is formed by an epitaxial growth method using CVD, ALD or molecular beam epitaxy (MBE). The first epitaxial layer 241 is grow from exposed semiconductor surfaces, i.e., the sidewall 216s of the semiconductor layer 216 and the top surface 236t of the bottom epitaxial layer 236. The first epitaxial source/drain layer 241 starts as discreet sections from the exposed semiconductor surfaces. For example, the first epitaxial source/drain layer 241 includes multiple sections grown from the sidewall 216s of the semiconductor layers 216.

The first epitaxial source/drain layer 241 is grown to a desired thickness to enable quality crystalline growth in the subsequent bulk epitaxial growth. The first epitaxial source/drain layer 241 may include one or more layers of Si, SiP, SiC and SiCP for NFET or Si, SiGe, Ge for a PFET. For the PFET, p-type dopants, such as boron (B), may also be included in the first epitaxial source/drain layer 241. For NFET, n-type dopants, such as arsenic (As), phosphorous (P), or carbon (C), or combinations thereof, may also be included in the first epitaxial source/drain layer 241.

In some embodiments, the semiconductor device 200 is a p-type device and the first epitaxial source/drain layer 241 includes Si or SiGe with a p-type dopant, such as B or Ga. In some embodiments, the first epitaxial source/drain layer 241 may be a SiGe layer with an atomic concentration of Ge in a range between about 0% and about 40%. In some embodiments, the first epitaxial source/drain layer 241 includes p-type dopants at a concentration between about 1E20 to about 2E21.

In some embodiments, the first epitaxial source/drain layer 241 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiC₁₂ (DCS), SiH₄, Si₂H₆, GeH₄, GeCl₄, HCl, Cl₂. In some embodiments, a p-type dopant precursor, such as B₂H₆, BCl₃, and Ga (CH₃)₃, may be used during deposition.

The bulk epitaxial source/drain layer 243 is formed over the first epitaxial source/drain layer 241. The bulk epitaxial source/drain layer 243 fills the source/drain recess 234. The first epitaxial source/drain layer 241 and the bulk epitaxial source/drain layer 243 form epitaxial source/drain regions 240.

The bulk epitaxial source/drain layer 243 is epitaxially grown from the first epitaxial source/drain layer 241. The bulk epitaxial source/drain layer 243 has a higher concentration of dopants than the first epitaxial source/drain layer 241. In some embodiments, composition of the bulk epitaxial source/drain layer 243 is also different from the first epitaxial source/drain layer 241. The bulk epitaxial source/drain layer 243 and the first epitaxial source/drain layer 241 have different crystalline structures. The bulk epitaxial source/drain layer 243 may include one or more layers of Si, SiP, SiC and SiCP for NFET or Si, SiGe, Ge for a PFET. For the PFET, p-type dopants, such as boron (B), are also included in the bulk epitaxial source/drain layer 243. For NFET, n-type dopants, such as arsenic (As), phosphorous (P), or carbon (C), or combinations thereof, are included in the bulk epitaxial source/drain layer 243.

In some embodiments, the semiconductor device 200 is a p-type device and the bulk epitaxial source/drain layer 243 includes Si or SiGe with a p-type dopant, such as B or Ga. In some embodiments, the bulk epitaxial source/drain layer 243 may be a SiGe layer with an atomic concentration of Ge in a range between about 20% and about 70%. In some embodiments, the bulk epitaxial source/drain layer 243 includes p-type dopants at a concentration between about 1E20 to about 3E21.

In some embodiments, the bulk epitaxial source/drain layer 243 may be formed by an epitaxial growth method using CVD, ALD or molecular beam epitaxy (MBE). In some embodiments, the epitaxial deposition process may be performed in a temperature range between about 400° C. and about 750° C., for example, between about 520° C. and about 620° C. In some embodiments, the epitaxial deposition process may be performed at a pressure in a range between about 10 torr and about 300 torr, for example, between about 20 torr and about 100 torr. In some embodiments, the epitaxial deposition process may use a precursor, such as H₂SiC₁₂ (DCS), SiH₄, Si₂H₆, GeH₄, GeCl₄, HCl, Cl₂. In some embodiments, a p-type dopant precursor, such as B₂H₆, BCl₃, and Ga (CH₃)₃, may be used during deposition.

As shown in FIG. 2K, the epitaxial source/drain regions 240 are grown pass the topmost semiconductor channel, i.e., the second semiconductor layer 216 under the sacrificial gate structure 228, to be in contact with the gate sidewall spacers 230. The first semiconductor layers 214 under the sacrificial gate structure 228 are separated from the epitaxial source/drain regions 240 by the inner spacers 232. The epitaxial source/drain region 240 is in contact with the bottom dielectric layer 238, which in turn provides isolation between the epitaxial source/drain region 240 and the well portion 212.

In operation 122, a contact etch stop layer (CESL) 242 and an interlayer dielectric (ILD) layer 244 are formed over the exposed surfaces as shown in FIG. 2L. FIG. 2L is a schematic cross-sectional view of the semiconductor device 200. The CESL 242 is formed on the epitaxial source/drain regions 240 and the gate sidewall spacers 230. In some embodiments, the CESL 242 has a thickness in a range between about 1 nm and about 15 nm. The CESL 242 may include Si₃N₄, SiON, SiCN or any other suitable material, and may be formed by CVD, PVD, or ALD.

The interlayer dielectric (ILD) layer 244 is formed over the contract etch stop layer (CESL) 242. The materials for the ILD layer 244 include compounds comprising Si, O, C, and/or H, such as silicon oxide, SiCOH and SiOC. Organic materials, such as polymers, may be used for the ILD layer 244. After the ILD layer 244 is formed, a planarization operation, such as CMP, is performed to expose the sacrificial gate electrode layer 226 for subsequent removal of the sacrificial gate structures 228. The ILD layer 244 protects the epitaxial source/drain regions 240 during the removal of the sacrificial gate structures 228.

In operation 124, replacement gate structures 250 are formed in place of the sacrificial gate structures 228, as shown in FIG. 2M. FIG. 2M is a schematic cross-sectional view of the semiconductor device 200. The sacrificial gate structures 228 are first removed. Particularly, the sacrificial gate electrode layer 226 and the sacrificial gate dielectric layer 224 are removed sequentially to expose the channel portion. The first semiconductor layers 214 and the second semiconductor layers 216 are exposed. The first semiconductor layers 214 are then selectively removed using an etchant with a higher etch rate with respect to the first semiconductor layers 214 than the etch rate with respect to the second semiconductor layers 216. After the first semiconductor layers 214 are removed, the second semiconductor layers 216 are exposed resulting in a semiconductor channel region including the second semiconductor layers 216 in connection to the epitaxial source/drain regions 240.

The replacement gate structures 250 are then formed around the channel region. A gate dielectric layer 246 is formed around each of the second semiconductor layers 216 and a gate electrode layer 248 is formed on the gate dielectric layer 246. The gate dielectric layer 246 and the gate electrode layer 248 may be referred to as a replacement gate structure 250.

The gate dielectric layer 246 may be formed by CVD, ALD or any suitable method. In one embodiment, the gate dielectric layer 246 is formed using a highly conformal deposition process such as ALD in order to ensure the formation of a gate dielectric layer 246 having a uniform thickness around each of the second semiconductor layers 216. In some embodiments, the thickness of the gate dielectric layer 246 is in a range between about 1 nm and about 6 nm.

The gate dielectric layer 246 includes one or more layers of a dielectric material, such as silicon oxide, silicon nitride, or high-k dielectric material, other suitable dielectric material, and/or combinations thereof. Examples of high-k dielectric material include HfO₂, HfSiO, HfSION, HfTaO, HfTIO, HfZrO, zirconium oxide, aluminum oxide, titanium oxide, hafnium dioxide-alumina (HfO₂-Al₂O₃) alloy, other suitable high-k dielectric materials, and/or combinations thereof. In some embodiments, an interfacial layer (not shown) is formed between the second semiconductor layer 16 and the gate dielectric layer 246. In some embodiments, one or more work function adjustment layers (not shown) are interposed between the gate dielectric layer 246 and the gate electrode layer 248.

The gate electrode layer 248 is formed on the gate dielectric layer 246 to surround each of the second semiconductor layer 216 (i.e., each channel) and the gate dielectric layer 246. The gate electrode layer 248 includes one or more layers of conductive material, such as polysilicon, aluminum, copper, titanium, tantalum, tungsten, cobalt, molybdenum, tantalum nitride, nickel silicide, cobalt silicide, TiN, WN, TiAI, TiAIN, TaCN, TaC, TaSiN, metal alloys, other suitable materials, and/or combinations thereof. The gate electrode layer 248 may be formed by CVD, ALD, electro-plating, or other suitable method.

After the formation of the gate electrode layer 248, a planarization process, such as a CMP process, is performed to remove excess deposition of the gate electrode material and expose the top surface of the ILD layer 244. In some embodiments, source/drain contacts 252 are formed through the ILD layer 244. Prior to forming the front side source/drain contacts 252, contact holes are formed in the ILD layer 244, the CESL 242, and a portion of the epitaxial source/drain regions 240.

After formation of the front side source/drain contacts 252 are formed, a front side interconnect structure (not shown) is formed by a middle end of line process. The front side interconnect structure includes multiple dielectric layers having metal lines and vias formed therein. The metal lines and vias in the front side interconnect structure may be formed of copper or copper alloys using one or more damascene processes. The front side interconnect structure may include multiple sets of inter-layer dielectric (ILD) layers and inter-metal dielectrics (IMDs) layers.

Referring to FIG. 2M, the bottom isolation layer 238 and the bottom most inner spacers 232 isolate the source/drain region 240 from the well portion 212 and the bottom epitaxial layer 236, preventing leak currents through the well portion 236. In some embodiments, the entire bottom isolation layer 238 is positioned below the lower most channel layer, i.e. the semiconductor layer 216L. A center of the lower most channel layer 216L is at a height H1 over the top surface 238t of the bottom isolation layer 238. In some embodiments, the height H1 is in a range between about 4.5 nm and about 8.5 nm. A center of a second channel layer 216 is at a height H2 over the top surface 238t of the bottom isolation layer 238. In some embodiments, the height H2 is in a range between about 17 nm and about 23 nm. A center of a third channel layer 216 is at a height H3 over the top surface 238t of the bottom isolation layer 238. In some embodiments, the height H3 is in a range between about 32 nm and about 38 nm.

FIG. 2N is a partially enlarged view of the semiconductor device 200 in a rectangular area 2N marked in FIG. 2M. FIG. 20 is a schematic cross-section view of the semiconductor device 200 along the line 20-20 in FIG. 2N. As shown in FIG. 2N, the top surface 238t of the bottom isolation layer 238 are in contact with the source/drain region 240. In some embodiments, as shown in FIG. 20, the bottom dielectric layer 238 may extend over the isolation region 222. The bottom isolation layer 238 may also in contact with the CESL 242.

In some embodiments, one or more elements in the bottom isolation layer 238 may have a concentration gradient along the z-direction. As discussed in operation 116, the first material layer 260 is converted to the dielectric material 262 by exposing an oxidizing agent, a nitriding agent, and/or a carbon source from via the top surface 260t. As a result, the concentration of oxygen, nitrogen, or carbon in the bottom isolation layer 238 may decrease from the top surface 238t. FIG. 2P schematically illustrates a concentration of oxygen/nitrogen/carbon in the bottom isolation layer 238 along the z-direction.

FIGS. 3A-3C schematically illustrate a semiconductor device 300 according to some embodiments of the present disclosure. FIG. 3A is a partial cross-sectional view of the semiconductor device 300. FIG. 3B is a cross-section view of the semiconductor device 300 along the 3B-3B line in FIG. 3A.

The semiconductor device 300 is similar to the semiconductor device 200 except that the semiconductor device 300 includes a bottom isolation layer 338 formed by repeating the operations 112, 114, 116 two or more times. As a result, the bottom isolation layer 338 may include two or more sublayers 338ₙ vertically stacked together. Each sublayer 338ₙ may have a thickness T₃₃₈ₙ. In some embodiments, each sublayer 338ₙ may have a substantially the same thickness. In some embodiments, the thickness T₃₃₈ₙ of the sublayer 338ₙ is in a range between about 0.5 nm and about 2.0 nm. In FIGS. 3A-3B, four sublayers 338₁, 338₂, 338₃, and 338₄ are shown in the semiconductor device 300. Less or more sublayers 338n may be formed according to circuit design and process sequence.

In some embodiments, concentrations of oxygen/nitrogen/carbon in the sublayers 338ₙ vary along the z-direction. As a result, concentration of oxygen/nitrogen/carbon in the bottom isolation layer 338 may have spikes along the z-direction. FIG. 3C schematically illustrates oxygen/nitrogen/carbon concentration in the bottom isolation layer 338 along the z-direction.

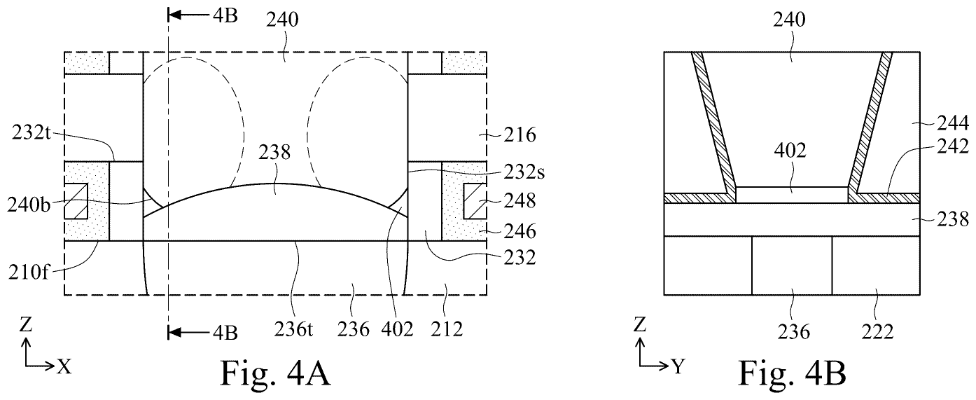

FIG. 4A-4B schematically illustrate a semiconductor device 400 according to some embodiments of the present disclosure. FIG. 4A is a partial cross-sectional view of the semiconductor device 400. FIG. 4B is a cross-section view of the semiconductor device 400 along the 4B-4B line in FIG. 4A.

The semiconductor device 400 is similar to the semiconductor device 200 except that the semiconductor device 400 includes air gaps 402 disposed between the bottom isolation layer 238 and the source/drain region 240. The air gaps 420 may be formed when the source/drain region 240 contacts the top surface 238t of the bottom isolation layer 238 before completely filling the space adjacent the bottom most inner spacers 232.

As shown in FIG. 4A, the air gaps 402 are defined between the side surfaces 232s of the bottom most inner spacers 232, the top surface 238t of the bottom isolation layer 238, and a bottom surface 240b of the source/drain region 240. As shown in FIG. 4B, the air gaps 402 extend along the y-direction and may be sealed by the CESL 242. The bottom isolation layer 238 along with the air gaps 402 provides electrical isolation around the source/drain region 240.

Various embodiments or examples described herein offer multiple advantages over the state-of-art technology. Embodiments of the present disclosure provide a method for forming high quality isolation layer improves bottom isolation and prevents leaks around the source/drain regions.

It will be understood that not all advantages have been necessarily discussed herein, no particular advantage is required for all embodiments or examples, and other embodiments or examples may offer different advantages.

Some embodiments of the present provide a method. The method comprises forming a semiconductor fin on a top surface of a semiconductor substrate, wherein the semiconductor fin comprises first semiconductor layers and second semiconductor layers alternately arranged; forming a recess through the semiconductor fin and into the semiconductor substrate; forming a bottom isolation layer in the recess comprising: depositing a first material layer; trimming the first material layer; and treating the first material layer to convert the first material layer into a dielectric-containing material layer; and growing an epitaxial source/drain region over the bottom isolation layer.

Some embodiments provide a method for forming a semiconductor device. The method comprises forming a semiconductor fin on a top surface of a semiconductor substrate, wherein the semiconductor fin comprises first semiconductor layers and second semiconductor layers alternately arranged; forming a recess through the semiconductor fin and into the semiconductor substrate; selectively etching back the first semiconductor layers to form inner spacers between the second semiconductor layers; growing a bottom epitaxial layer in the recess; forming a bottom isolation layer, wherein a bottom surface of the bottom isolation layer is in contact with the bottom epitaxial layer, a top surface of the bottom isolation layer intersects with bottom most inner spacers, and a concentration of an element in the bottom isolation layer varies from the top surface to the bottom surface; and growing an epitaxial source/drain region over the bottom dielectric layer.

Some embodiments of the present provide a semiconductor device. The semiconductor device includes a semiconductor substrate; two or more semiconductor channel layers vertically stacked above a top surface of the semiconductor substrate; two or more inner spacers disposed alternately stacked with the two or more semiconductor channel layers; an epitaxial source/drain region connected to the two or more semiconductor channel layers; and a bottom isolation layer, wherein a top surface of the bottom isolation layer is in contact with a bottom surface of the epitaxial source/drain region, the top surface of the bottom isolation layer intersects with a side surface of a bottom most inner spacer, and the top surface of the bottom isolation layer has a convex profile.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Claims:

1. A method comprising:
forming a semiconductor fin on a top surface of a semiconductor substrate, wherein the semiconductor fin comprises first semiconductor layers and second semiconductor layers alternately arranged;
forming a recess through the semiconductor fin and into the semiconductor substrate;
forming a bottom isolation layer in the recess comprising:
depositing a first material layer;
trimming the first material layer; and
treating the first material layer to convert the first material layer into a dielectric-containing material layer; and
growing an epitaxial source/drain region over the bottom isolation layer.

2. The method of claim 1, further comprising:
performing an etching process to remove the dielectric-containing material layer from vertical surfaces prior to growing the epitaxial source/drain region.

3. The method of claim 2, wherein forming a bottom isolation layer comprising:
repeating the depositing, trimming and treating prior to performing the etching process.

4. The method of claim 1, wherein the first material layer is a silicon layer.

5. The method of claim 4, wherein treating the first material layer comprises exposing the first material layer to an oxygen source, a nitrogen source, or a carbon source.

6. The method of claim 1, wherein the first material layer is a metal layer.

7. The method of claim 6, wherein treating the first material layer comprises exposing the first material to an oxygen source.

8. The method of claim 1, further comprising:
selectively etching back the first semiconductor layers to form inner spacers between the second semiconductor layers.

9. The method of claim 8, further comprising forming an air gap, wherein the air gap is defined by the bottom most inner spacer, the bottom isolation layer and the source/drain region.

10. A method comprising:
forming a semiconductor fin on a top surface of a semiconductor substrate, wherein the semiconductor fin comprises first semiconductor layers and second semiconductor layers alternately arranged;
forming a recess through the semiconductor fin and into the semiconductor substrate;
selectively etching back the first semiconductor layers to form inner spacers between the second semiconductor layers;
growing a bottom epitaxial layer in the recess;
forming a bottom isolation layer, wherein a bottom surface of the bottom isolation layer is in contact with the bottom epitaxial layer, a top surface of the bottom isolation layer intersects with bottom most inner spacers, and a concentration of an element in the bottom isolation layer varies from the top surface to the bottom surface; and
growing an epitaxial source/drain region over the bottom dielectric layer. 11 The method of claim 10, wherein forming the bottom isolation layer comprises:
depositing a first material layer over the bottom epitaxial layer; and
treating the first material layer with the element to convert the first material layer into a dielectric-containing material layer.

12. The method of claim 11, further comprising:
trimming the first material layer prior to treating the first material layer with the element.

13. The method of claim 12, wherein the concentration of the element in the bottom isolation layer decreases from the top surface to the bottom surface.

14. The method of claim 12, further comprising, repeating depositing, trimming, and treating.

15. The method of claim 14, wherein the concentration of the element in the bottom isolation layer includes one or more spikes from the top surface to the bottom surface.

16. A device, comprising:
a substrate;
two or more channel layers vertically stacked above a top surface of the substrate;
two or more inner spacers disposed alternately stacked with the two or more channel layers;
a source/drain region connected to the two or more semiconductor channel layers; and
a bottom isolation layer, wherein a top surface of the bottom isolation layer is in contact with the epitaxial source/drain region, the top surface of the bottom isolation layer intersects with a side surface of a bottom most inner spacer, and the top surface of the bottom isolation layer has a convex profile.

17. The semiconductor device of claim 16, wherein the bottom isolation layer contains a first element, and a concentration of the first element varies from the top surface to a bottom surface.

18. The semiconductor device of claim 17, wherein the concentration of the first element decreases from the top surface to the bottom surface.

19. The semiconductor device of claim 17, wherein the concentration of the first element includes spikes from the top surface to the bottom surface.

20. The semiconductor device of claim 16, wherein an air gap is defined by the side surface of the bottom most inner spacer, the top surface of the bottom isolation layer, and the source/drain region.
